(19) United States
(12) Patent Application Publication
(10) Pub. No.: US 2026/0282965 A1
(43) Pub. Date: Sep. 17, 2026

(54) Semiconductor Device and Method of Forming Stacked Encapsulated Conductive Pillar Layers as Vertical Interconnect Structure

(71) Applicant: STATS ChipPAC Pte. Ltd., Singapore (SG)

(72) Inventors: Yi Xiang Jasper Tay, Singapore (SG); Swain Hong Alfred Yeo, Singapore (SG); Chee Meng Law, Johor Bahru (MY); Junyi Zeng, Singapore (SG); Peik Eng Ooi, Singapore (SG)

(73) Assignee: STATS ChipPAC Pte. Ltd., Singapore (SG)

(21) Appl. No.: 19/081,250

(22) Filed: Mar. 17, 2025

(51) Int. Cl. H01L 23/498; H01L 21/321; H01L 21/56; H01L 21/768; H01L 23/00; H01L 23/31

(52) U.S. Cl. CPC H10W 70/65; H10P 95/04; H10W 20/063; H10W 20/069; H10W 20/082; H10W 74/01; H10W 74/10; H10W 72/012; H10W 72/01223; H10W 72/01235; H10W 72/01238; H10W 72/0198; H10W 72/07232; H10W 72/07236; H10W 72/252; H10W 90/724

(57) ABSTRACT

A semiconductor device has a vertical interconnect structure with a first conductive pillar and a first encapsulant deposited around the first conductive pillar. A second conductive pillar is formed over the first conductive pillar. A second encapsulant is deposited around the second conductive pillar. Additional conductive pillars and encapsulant deposited around the conductive pillars can be formed to extend a height of the vertical interconnect structure. The first conductive pillar can have an angled sidewall or a vertical sidewall. The second conductive pillar can have an angled sidewall or a vertical sidewall. A surface of the second conductive pillar as exposed from the second encapsulant is planarized. A width of the first conductive pillar is different from a width of the second conductive pillar. A pitch of a sidewall of the first conductive pillar is different from a pitch of a sidewall of the second conductive pillar.

### FIELD OF THE INVENTION

The present invention relates in general to semiconductor devices and, more particularly, to a semiconductor device and method of forming stacked encapsulated conductive pillar layers as a vertical interconnect structure.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor die are commonly mounted to an interconnect substrate to provide interconnectivity. The interconnect substrate provides vertical and horizontal signal paths for the semiconductor die. The vertical signal paths are made with conductive vias extending through the interconnect substrate. The conductive vias are formed in photoresist material or a passivation layer. Accordingly, the height of the conductive vias is limited by the thickness of the photoresist or passivation material. To gain additional vertical interconnect height, the conductive vias can be stacked. However, the photoresist and passivation material can lead to misalignment of the conductive vias and resulting defects. High warpage is common among stacked conductive vias formed in photoresist and passivation material. It is difficult to alter the height to width ratio of the stacked conductive vias formed in photoresist and passivation material.

### BRIEF DESCRIPTION OF THE DRAWINGS

FIGS. 1a-1e illustrate a semiconductor wafer with a plurality of semiconductor die separated by a saw street;

FIGS. 2a-2t illustrate a process of forming a vertical interconnect structure with stacked encapsulated conductive pillar layers;

FIG. 3 illustrates semiconductor equipment to perform the dual exposure of the photoresist layer;

FIGS. 4a-4q illustrate another process of forming a vertical interconnect structure with stacked encapsulated conductive pillar layers;

FIG. 5 illustrates the vertical interconnect structure with stacked encapsulated conductive pillars of different width;

FIG. 6 illustrates the vertical interconnect structure with stacked encapsulated conductive pillars of different pitches; and

FIG. 7 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

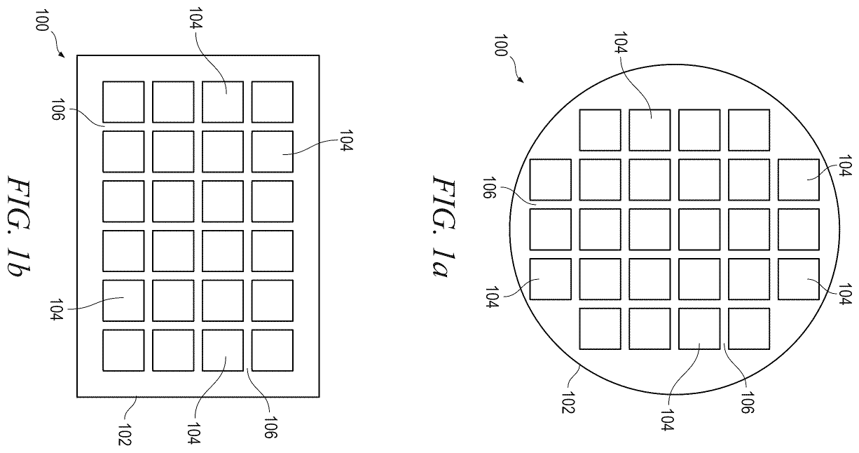

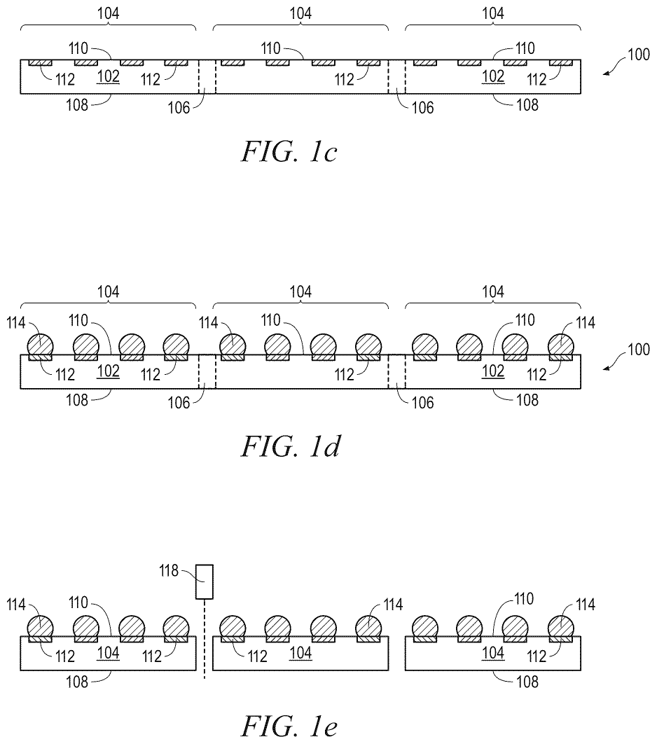

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular, as shown in FIG. 1b, or any other geometric shape.

FIG. 1c shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1d, an electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1e, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

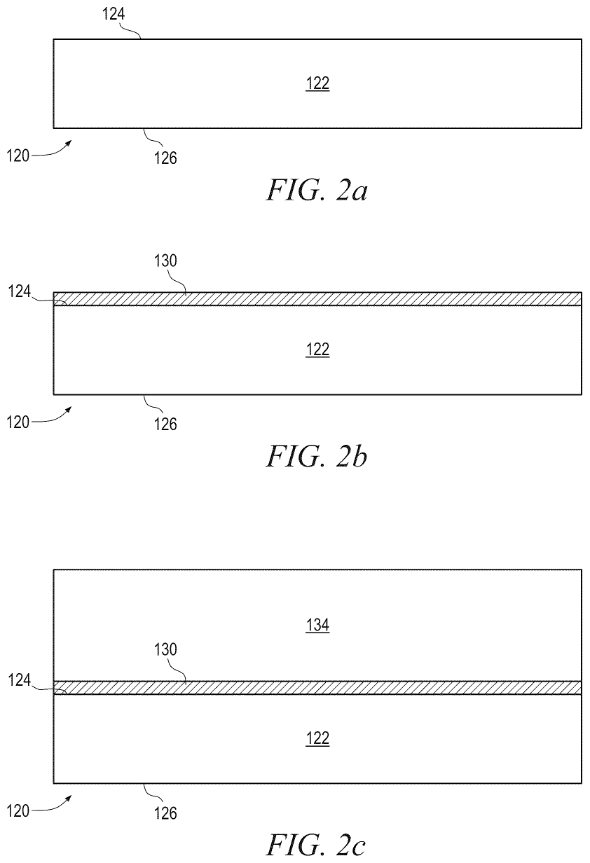

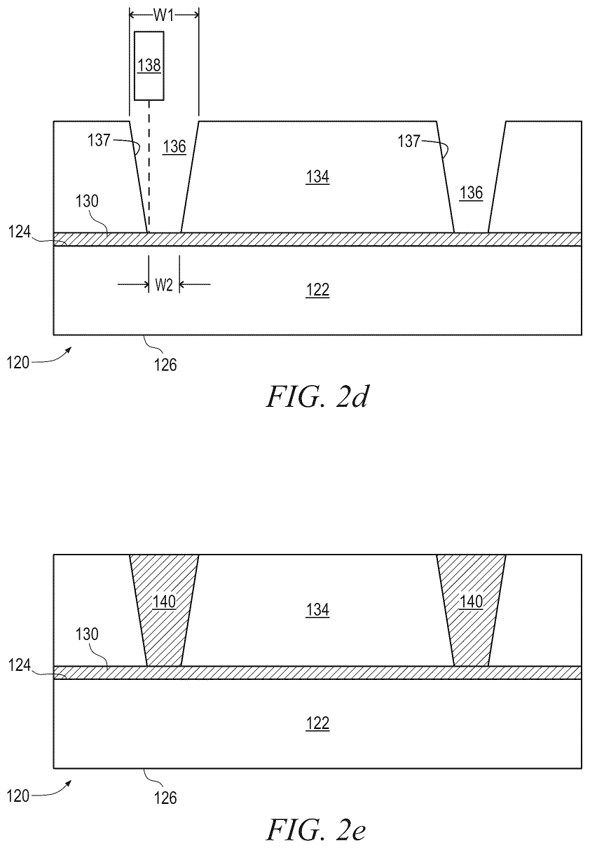

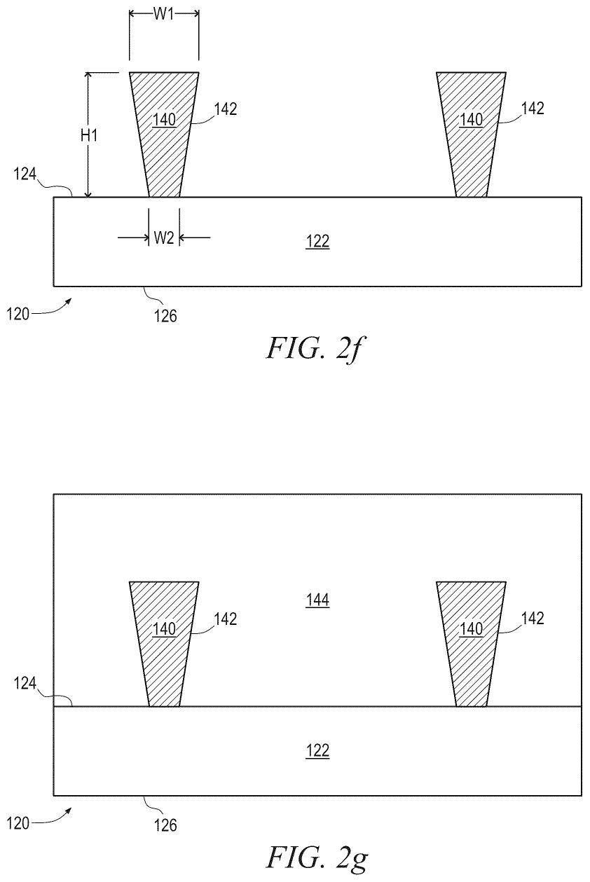

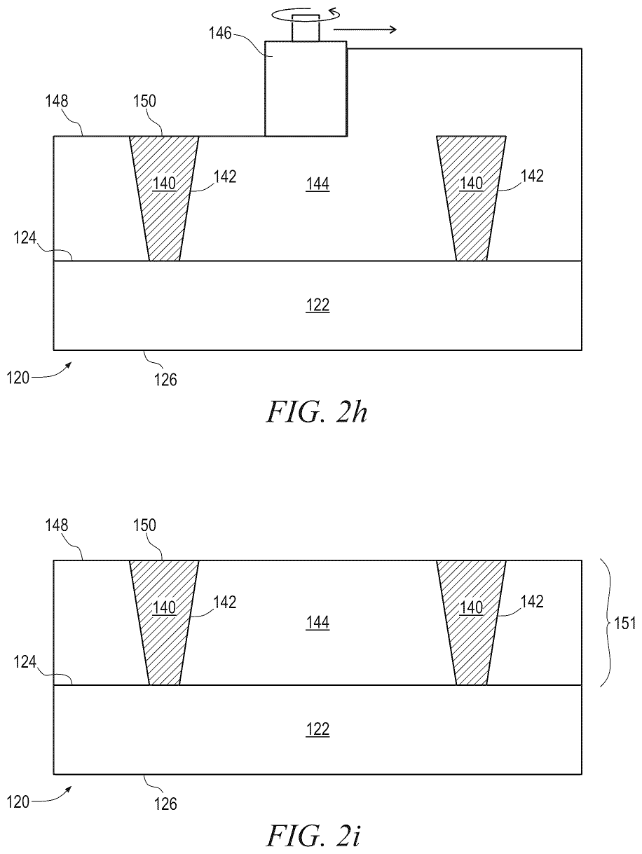

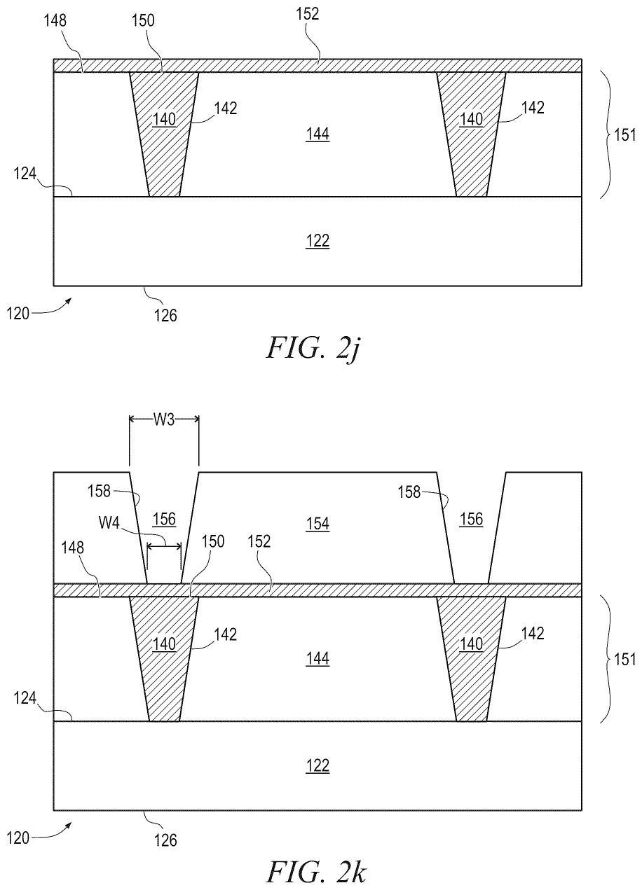

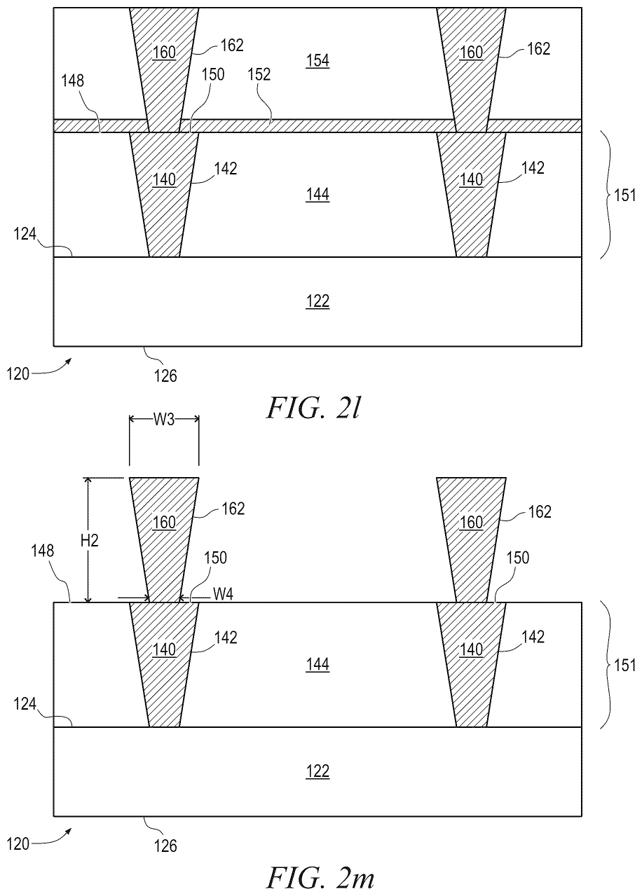

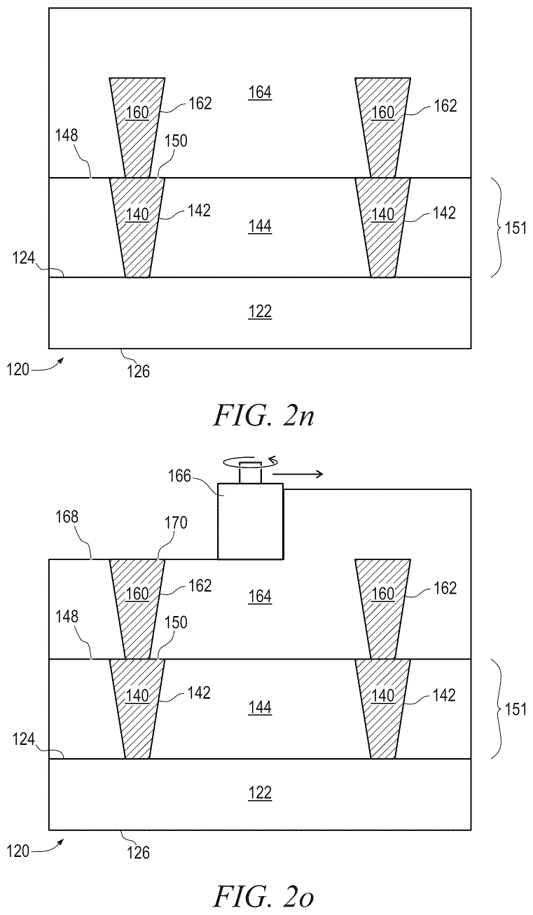

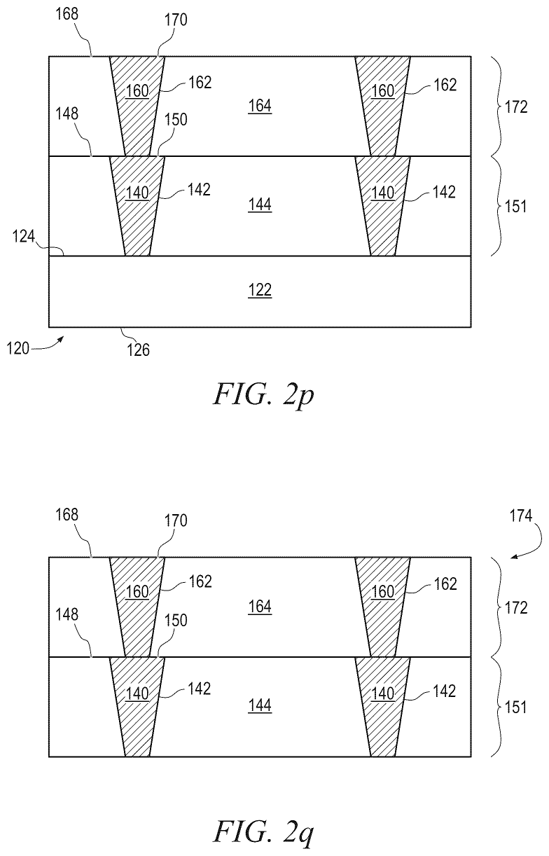

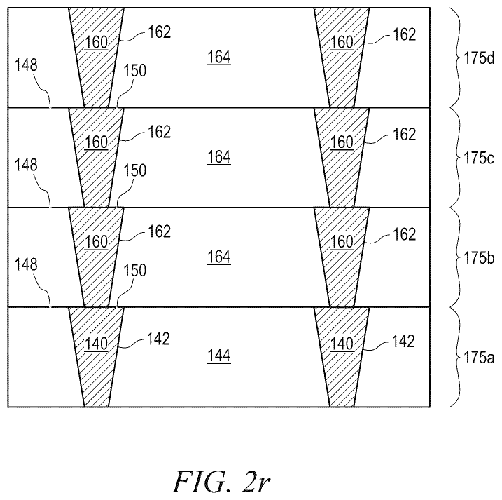

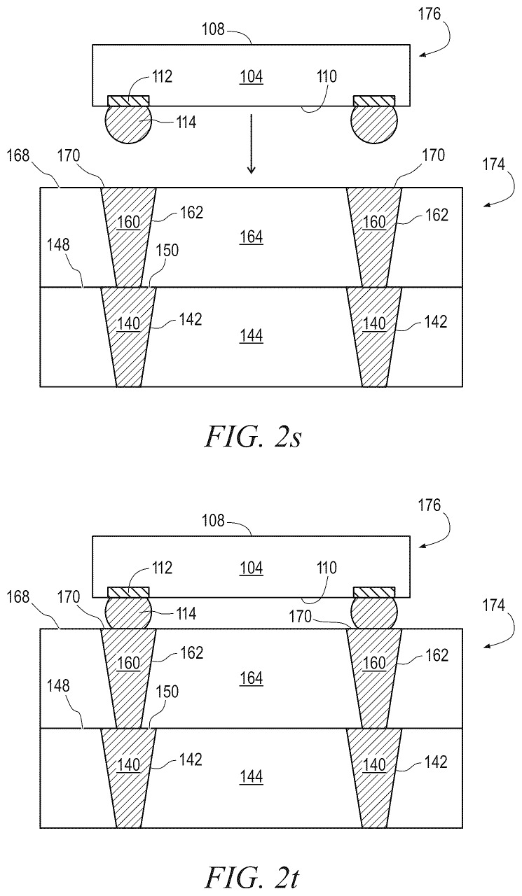

FIGS. 2a-2t illustrate a process of forming stacked encapsulated conductive pillar layers as a vertical interconnect structure. FIG. 2a shows a cross-sectional view of temporary substrate or carrier 120 including top major surface 124 and bottom major surface 126. Substrate 120 can be a sacrificial base material 122, such as silicon, polymer, beryllium oxide, glass, Cu plate, molded wafer, or other suitable low-cost, rigid material for structural support.

In FIG. 2b, a seed layer 130 is formed over surface 124 using PVD, CVD, electrolytic plating, electroless plating process, or other suitable metal deposition process.

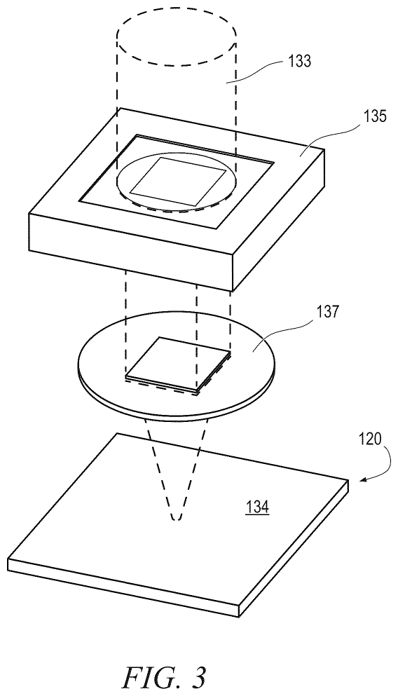

In FIG. 2c, a photoresist layer 134 is formed over seed layer 130. A portion of photoresist layer 134 is removed using reticle mask 135 to define the area of exposure to form conductive pillars, as shown in FIG. 3. A light 133 is propagated through reticle mask 135 and lens 137 to a location on photoresist layer 134 intended for the formation of conductive pillars. The photoresist is dual exposed to reduce misalignment and then developed, and an etching process removes the developed portion of photoresist layer 134, leaving openings 136 with width W1 of 80.0 micrometers (mm) and angled or pitched sidewalls 137 narrowing to width W2 of 60.0 μm, as in FIG. 2 d. Alternatively, openings 136 with angled sidewalls 137 can be formed by laser direct ablation (LDA) using laser 138.

In FIG. 2e, an electrically conductive material is deposited in openings 136 using PVD, CVD, electrolytic plating, electroless plating process, or other suitable metal deposition process to form conductive pillars 140. Conductive pillars 140 can be one or more layers of Al, Cu, Sn, Ni, Au, Ag, or other suitable electrically conductive material. Conductive pillars 140 coalesce with the portion of seed layer 130 within openings 136.

In FIG. 2f, the remaining portion of photoresist layer 134 and seed layer 130 is removed, leaving conductive pillars 140 formed over substrate 120. Conductive pillars 140 have an angled side surface 142 by nature of openings 136 having angled side walls 137. Conductive pillars 140 have height H1 of 100.0 μm, width W1 of 80.0 μm at the top surface, and width W2 of 60.0 μm at the base of the pillars.

In FIG. 2g, encapsulant 144 is deposited over surface 124 and around conductive pillars 140. Encapsulant 144 can be polymer composite material, such as epoxy resin with filler, epoxy acrylate with filler, or polymer with proper filler. Encapsulant 144 is non-conductive, provides structural support, and environmentally protects the semiconductor device from external elements and contaminants.

In FIG. 2h, a portion of encapsulant 144 is removed by grinder 146 to planarize and expose surface 148 of the encapsulant and surface 150 of conductive pillars 140. FIG. 2i shows planarized surface 148 of encapsulant 144 and planarized surface 150 of conductive pillars 140. Conductive pillar 140 embedded within encapsulant 144 constitutes a first encapsulated conductive pillar layer 151.

In FIG. 2j, a seed layer 152 is formed over surface 148 and surface 150 using PVD, CVD, electrolytic plating, electroless plating process, or other suitable metal deposition process.

In FIG. 2k, a photoresist layer 154 is formed over seed layer 152, similar to FIG. 2c. A portion of photoresist layer 154 is removed using a reticle mask to define the area of exposure to form conductive pillars, similar to FIG. 3. A light is propagated through the reticle mask and lens to a location on photoresist layer 154 intended for the formation of second conductive pillars over conductive pillars 140. The photoresist is dual exposed to reduce misalignment and then and developed, and an etching process removes the developed portion of photoresist layer 154, leaving openings 156 with width W3 of 80.0 μm and angled sidewalls 158 narrowing to width W4 of 60.0 μm over conductive pillars 140. Alternatively, openings 156 with angled or pitched sidewalls 158 can be formed by LDA, similar to FIG. 2d.

In FIG. 2l, an electrically conductive material is deposited in openings 156 using PVD, CVD, electrolytic plating, electroless plating process, or other suitable metal deposition process to form conductive pillars 160. Conductive pillars 160 can be one or more layers of Al, Cu, Sn, Ni, Au, Ag, or other suitable electrically conductive material. Conductive pillars 160 coalesce with the portion of seed layer 152 within openings 156.

In FIG. 2m, the remaining portion of photoresist layer 154 and seed layer 152 is removed, leaving conductive pillars 160 formed over conductive pillars 140. Conductive pillars 160 have an angled or pitched side surface 142 by nature of openings 136 having angled or pitched side walls 137. Conductive pillars 160 have height H2 of 100.0 μm, width W3 of 80.0 μm at the top surface, and width W4 of 60.0 μm at the base of the pillars.

In FIG. 2n, encapsulant 164 is deposited over surface 148 and around conductive pillars 160. Encapsulant 164 can be polymer composite material, such as epoxy resin with filler, epoxy acrylate with filler, or polymer with proper filler. Encapsulant 164 is non-conductive, provides structural support, and environmentally protects the semiconductor device from external elements and contaminants.

In FIG. 2o, a portion of encapsulant 164 is removed by grinder 166 to planarize and expose surface 168 of the encapsulant and surface 170 of conductive pillars 160. FIG. 2p shows planarized surface 168 of encapsulant 164 and planarized surface 170 of conductive pillars 160. Conductive pillar 160 embedded within encapsulant 164 constitutes a second encapsulated conductive pillar layer 172.

In FIG. 2q, substrate 120 is removed by chemical etching, chemical mechanical polishing (CMP), mechanical peel-off, mechanical grinding, thermal bake, ultra-violet (UV) light, or wet stripping to expose conductive pillars 140. The stacked encapsulated conductive pillar layers 151 and 172 constitute vertical interconnect structure 174. Conductive pillars 140 are embedded in encapsulant 144 and conductive pillars 160 are embedded in encapsulant 164. Encapsulated conductive pillar layer 172 is stacked over encapsulated conductive pillar layer 151 to provide higher vertical interconnect. Vertical interconnect structure 174 can have any number of stacked encapsulated conductive pillar layers like 151 and 172 by repeating the steps of FIGS. 2j-2p. For example, FIG. 2r shows four stacked encapsulated conductive pillar layers 175a-175d.

Encapsulant 144 provides support for conductive pillars 140 in vertical interconnect structure 174. Likewise, encapsulant 164 provides support for conductive pillars 160 for stacking. Encapsulant 144 and 164 provide more support than photoresist. Encapsulant 144 and 164 have improved control of coefficient of thermal expansion (CTE), as well as flexibility to control warpage. Vertical interconnect structure 174 is scalable for higher conductive pillars height to width ratios. The height of the conductive pillars can be scaled to optical connectivity. The stacked encapsulated conductive pillars 140 and 160 in vertical interconnect structure 174 can have multiple arrangements, pitches, and heights to accommodate the product application.

In FIG. 2s, one or more electrical components 176 are disposed over vertical interconnect structure 174 using a pick and place operation with bumps 114 oriented toward surface 170 of conductive pillars 160. In one embodiment, electrical component 176 can be semiconductor die 104 from FIG. 1e. Alternatively, electrical component 176 can include other semiconductor die, semiconductor packages, surface mount devices, discrete electrical devices, interconnect structures, or IPDs. FIG. 2t shows electrical component 176 mounted to vertical interconnect structure 174 with bumps 114 electrically and mechanically bonded to conductive pillars 160. Electrical components 176 can send and receive electrical signals through stacked encapsulated conductive pillars 140 and 160 of vertical interconnect structure 174 to other electrical devices.

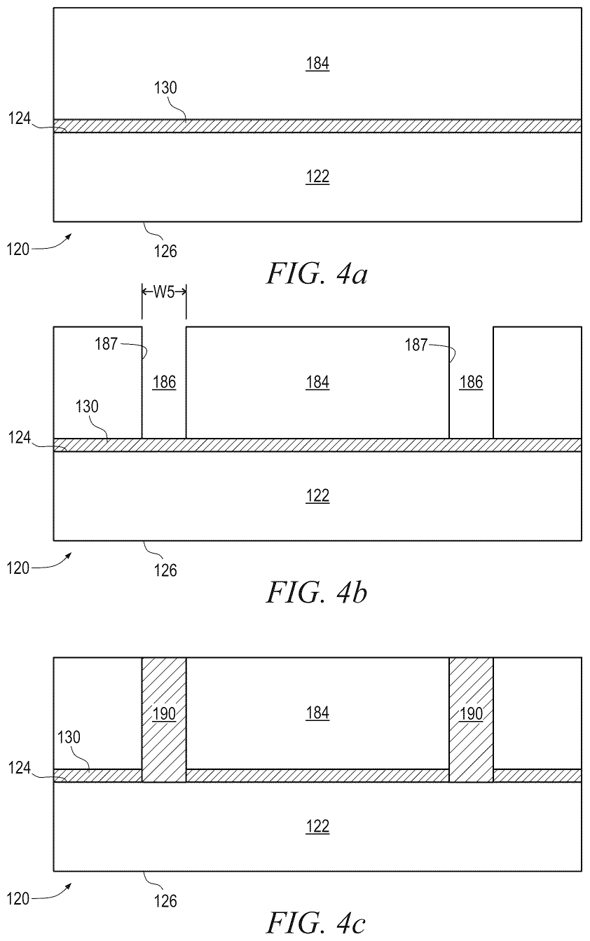

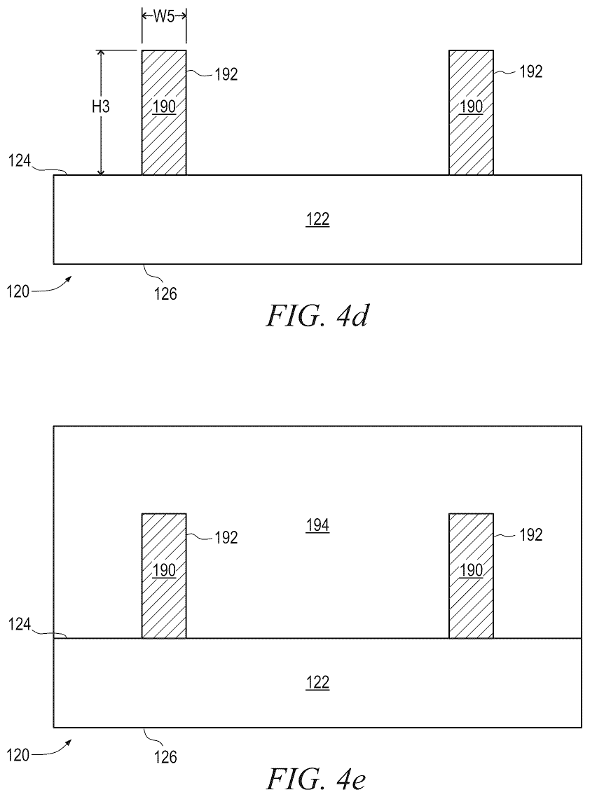

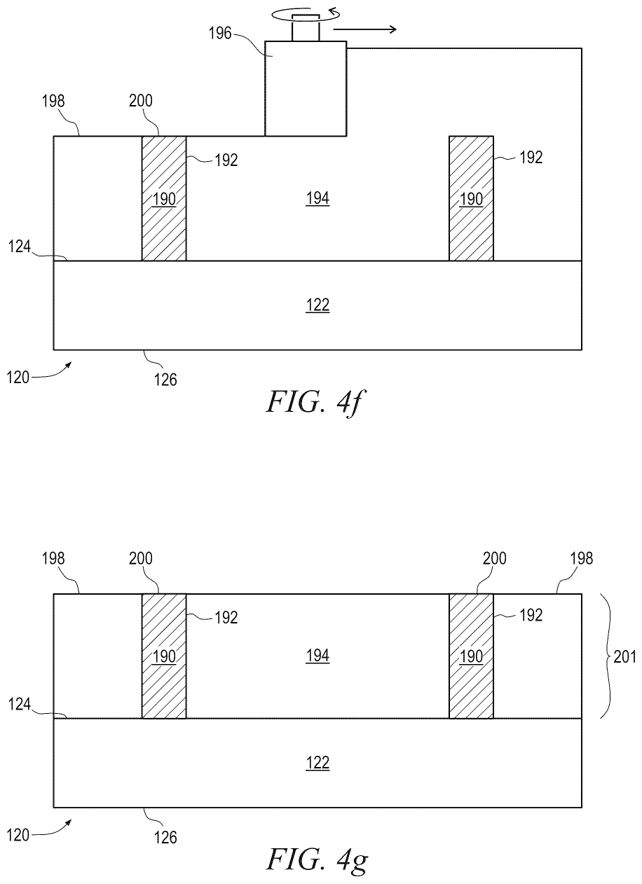

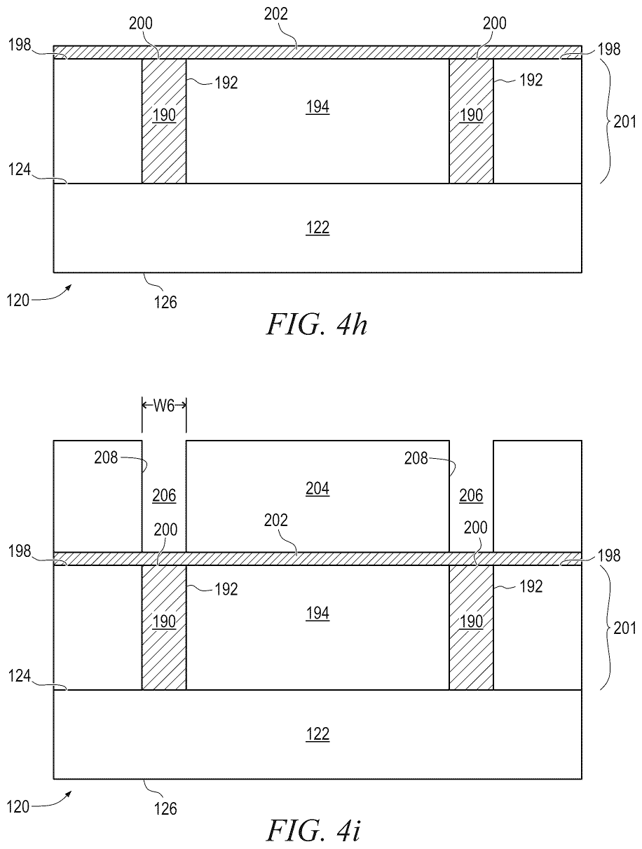

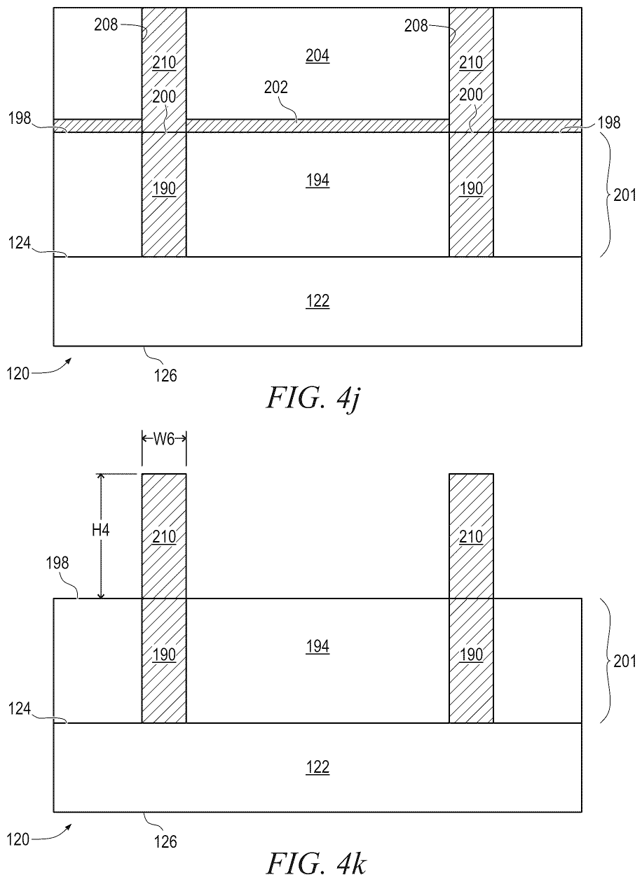

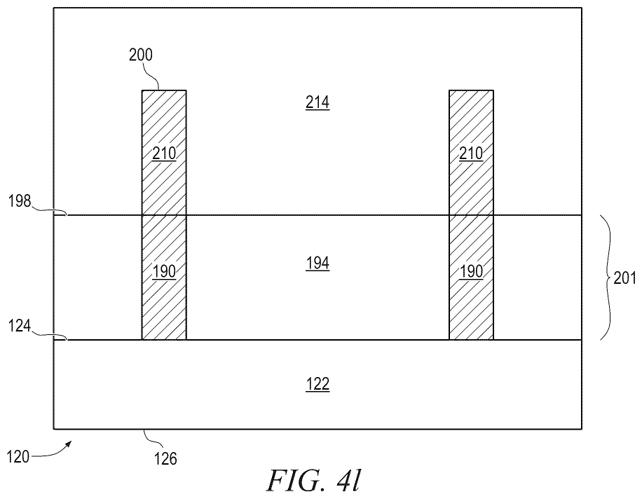

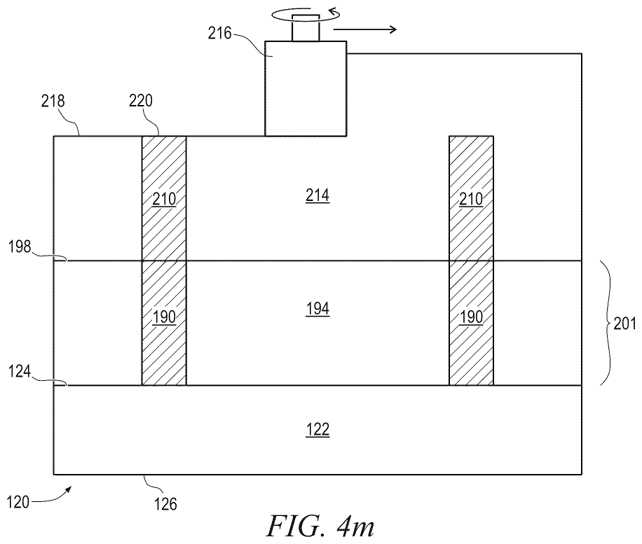

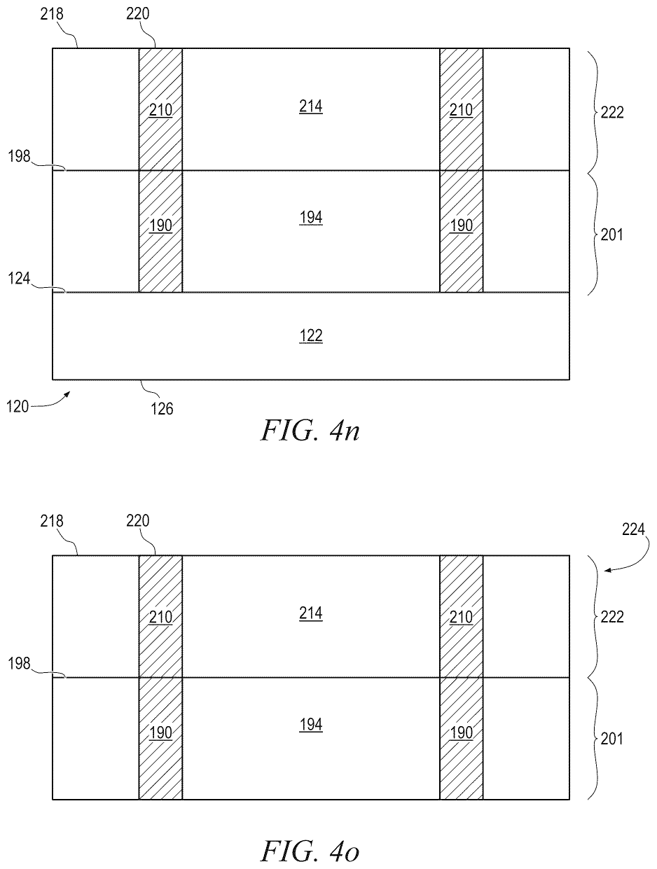

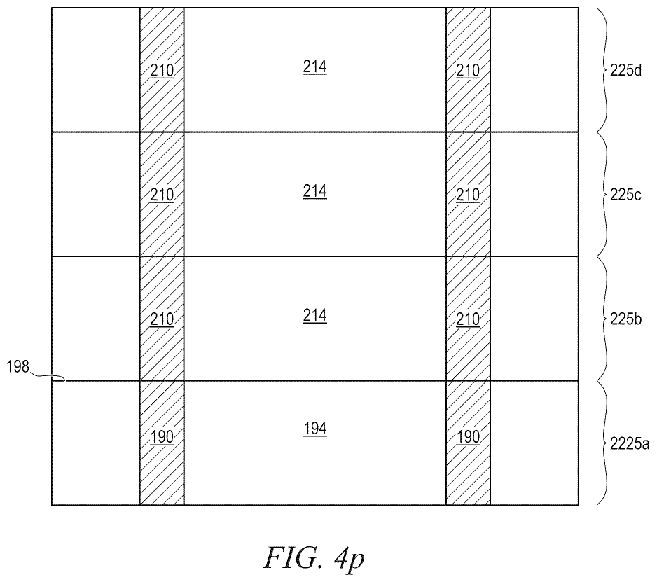

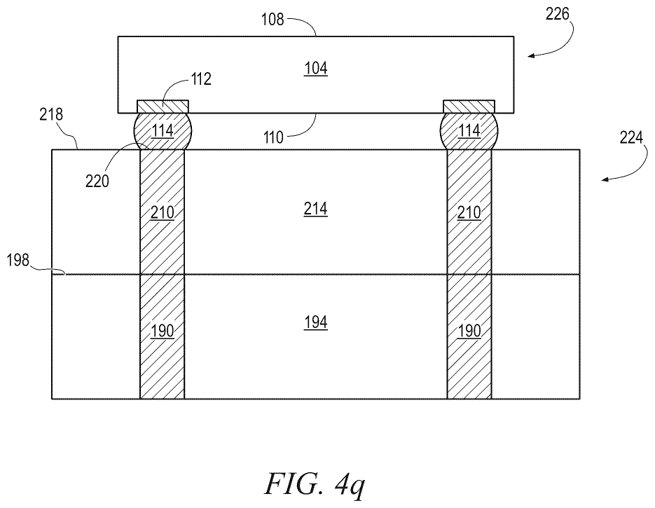

In another embodiment, continuing from FIG. 2b, a photoresist layer 184 is formed over seed layer 130, as shown in FIG. 4a. Elements having a similar function are assigned the same reference number. A portion of photoresist layer 184 is removed using a reticle mask to define the area of exposure to form conductive pillars, similar to FIG. 3. A light is propagated through the reticle mask and lens to a location on photoresist layer 184 intended for the formation of conductive pillars. The photoresist is dual exposed to reduce misalignment and then and developed, and an etching process removes the developed portion of photoresist layer 184, leaving openings 186 with width W5 of 60.0 μm and vertical sidewalls 187, as in FIG. 4b. Alternatively, openings 186 with vertical sidewalls 187 can be formed by LDA, similar to FIG. 2d.

In FIG. 4c, an electrically conductive material is deposited in openings 186 using PVD, CVD, electrolytic plating, electroless plating process, or other suitable metal deposition process to form conductive pillars 190. Conductive pillars 190 can be one or more layers of Al, Cu, Sn, Ni, Au, Ag, or other suitable electrically conductive material. Conductive pillars 190 coalesce with the portion of seed layer 130 within openings 186.

In FIG. 4d, the remaining portion of photoresist layer 184 and seed layer 130 is removed, leaving conductive pillars 190 formed over substrate 120. Conductive pillars 190 have a vertical side surface 192 by nature of openings 186 having vertical side walls 187. Conductive pillars 190 have height H3 of 100.0 μm and width W5 of 60.0 μm.

In FIG. 4e, encapsulant 194 is deposited over surface 124 and around conductive pillars 190. Encapsulant 194 can be polymer composite material, such as epoxy resin with filler, epoxy acrylate with filler, or polymer with proper filler. Encapsulant 194 is non-conductive, provides structural support, and environmentally protects the semiconductor device from external elements and contaminants.

In FIG. 4f, a portion of encapsulant 194 is removed by grinder 196 to planarize and expose surface 198 of the encapsulant and surface 200 of conductive pillars 190. FIG. 4g shows planarized surface 198 of encapsulant 194 and planarized surface 200 of conductive pillars 190. Conductive pillar 190 embedded within encapsulant 194 constitutes a first encapsulated conductive pillar layer 201.

In FIG. 4h, a seed layer 202 is formed over surface 198 and surface 200 using PVD, CVD, electrolytic plating, electroless plating process, or other suitable metal deposition process.

In FIG. 4i, a photoresist layer 204 is formed over seed layer 202, similar to FIG. 2 c. A portion of photoresist layer 204 is removed using a reticle mask to define the area of exposure to form conductive pillars, similar to FIG. 3. A light is propagated through the reticle mask and lens to a location on photoresist layer 204 intended for the formation of second conductive pillars over conductive pillars 190. The photoresist is dual exposed to reduce misalignment and then and developed, and an etching process removes the developed portion of photoresist layer 204, leaving openings 206 with width W6 of 60.0 mm and vertical sidewalls 208 over conductive pillars 190. Alternatively, openings 206 with vertical sidewalls 208 can be formed by LDA, similar to FIG. 2d.

In FIG. 4j, an electrically conductive material is deposited in openings 206 using PVD, CVD, electrolytic plating, electroless plating process, or other suitable metal deposition process to form conductive pillars 210. Conductive pillars 210 can be one or more layers of Al, Cu, Sn, Ni, Au, Ag, or other suitable electrically conductive material. Conductive pillars 210 coalesce with the portion of seed layer 202 within openings 206.

In FIG. 4k, the remaining portion of photoresist layer 204 and seed layer 202 is removed, leaving conductive pillars 210 formed over conductive pillars 190. Conductive pillars 210 have a vertical side surface 212 by nature of openings 206 having vertical side walls 208. Conductive pillars 210 have height H4 of 100.0 μm and width W6 of 60.0 μm.

In FIG. 4l, encapsulant 214 is deposited over surface 198 and around conductive pillars 210. Encapsulant 214 can be polymer composite material, such as epoxy resin with filler, epoxy acrylate with filler, or polymer with proper filler. Encapsulant 214 is non-conductive, provides structural support, and environmentally protects the semiconductor device from external elements and contaminants.

In FIG. 4m, a portion of encapsulant 214 is removed by grinder 216 to planarize and expose surface 218 of the encapsulant and surface 220 of conductive pillars 210. FIG. 4n shows planarized surface 218 of encapsulant 214 and planarized surface 220 of conductive pillars 210. Conductive pillar 210 embedded within encapsulant 214 constitutes a second encapsulated conductive pillar layer 222.

In FIG. 4o, substrate 120 is removed by chemical etching, CMP, mechanical peel-off, mechanical grinding, thermal bake, UV light, or wet stripping to expose conductive pillars 210. The stacked encapsulated conductive pillar layers 201 and 222 constitute vertical interconnect structure 224. Conductive pillars 190 are embedded in encapsulant 194 and conductive pillars 210 are embedded in encapsulant 214. Encapsulated conductive pillar layer 222 is stacked over encapsulated conductive pillar layer 201 to provide higher vertical interconnect. Vertical interconnect structure 174 can have any number of stacked encapsulated conductive pillar layers like 201 and 222 by repeating the steps of FIGS. 4a-4o. For example, FIG. 4p shows four stacked encapsulated conductive pillar layers 225a-225d.

Encapsulant 194 provides support for conductive pillars 190 in vertical interconnect structure 224. Likewise, encapsulant 214 provides support for conductive pillars 210 for stacking. Encapsulant 194 and 214 provide more support than photoresist. Encapsulant 194 and 214 have improved control of CTE, as well as flexibility to control warpage. Vertical interconnect structure 224 is scalable for higher conductive pillars height to width ratios. The height of the conductive pillars can be scaled to optical connectivity. The stacked encapsulated conductive pillars 190 and 210 in vertical interconnect structure 224 can have multiple arrangements, pitches, and heights to accommodate the product application.

One or more electrical components 226 can be disposed over vertical interconnect structure 224 using a pick and place operation with bumps 114 oriented toward surface 220 of conductive pillars 210, similar to FIG. 2s. In one embodiment, electrical component 226 can be semiconductor die 104 from FIG. 1e. Alternatively, electrical component 226 can include other semiconductor die, semiconductor packages, surface mount devices, discrete electrical devices, interconnect structures, or IPDs. FIG. 4q shows electrical component 226 mounted to vertical interconnect structure 224 with bumps 114 electrically and mechanically bonded to conductive pillars 210. Electrical components 226 can send and receive electrical signals through stacked encapsulated conductive pillars 190 and 210 of vertical interconnect structure 224 to other electrical devices.

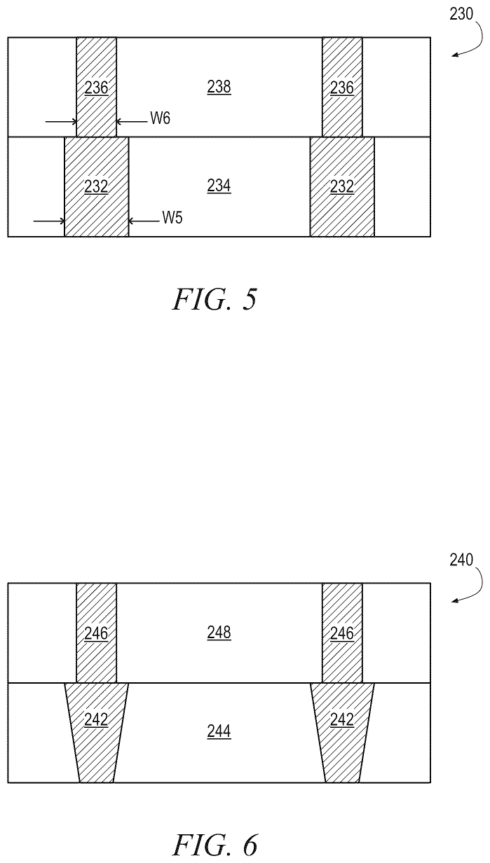

In another embodiment, the stacked encapsulated vertical sidewall conductive pillars can be made different widths. FIG. 5 shows vertical interconnect structure 230 with vertical sidewall conductive pillars 232 embedded within encapsulant 234, similar to FIGS. 4a-4g. The vertical sidewall conductive pillars 236 are embedded within encapsulant 238, similar to FIGS. 4h-4o. In this case, width W5 is greater than width W6. In one embodiment, width W5 is 80.0 μm and width W6 is 60.0 μm. Alternatively, width W6 can be made greater than width W5. The wider vertical sidewall conductive pillars 232 embedded within encapsulant 234 and narrower vertical sidewall conductive pillars 236 embedded within encapsulant 238 can be stacked to alternate between wider vertical sidewall conductive pillars 232 and narrower vertical sidewall conductive pillars 236. Alternatively, there can be a plurality of stacked wider vertical sidewall conductive pillars 232 embedded within encapsulant 234, followed by a plurality of stacked narrower vertical sidewall conductive pillars 236 embedded within encapsulant 238.

In another embodiment, the stacked encapsulated conductive pillars can be made with a combination of angled or pitched sidewall conductive pillars and vertical sidewall conductive pillars. FIG. 6 shows vertical interconnect structure 240 with angled sidewall conductive pillars 242 embedded within encapsulant 234, similar to FIGS. 2a-2i. The vertical sidewall conductive pillars 246 are embedded within encapsulant 248, similar to FIGS. 4h-4o. Conductive pillars 242 with angled sidewalls have a different pitch as conductive pillars 246 with vertical sidewalls. The angled sidewall conductive pillars 242 embedded within encapsulant 244 and vertical sidewall conductive pillars 246 embedded within encapsulant 248 can be stacked to alternate between angled sidewall conductive pillars 242 and vertical sidewall conductive pillars 246. Alternatively, there can be a plurality of stacked angled sidewall conductive pillars 242 embedded within encapsulant 244, followed by a plurality of stacked vertical sidewall conductive pillars 246 embedded within encapsulant 248.

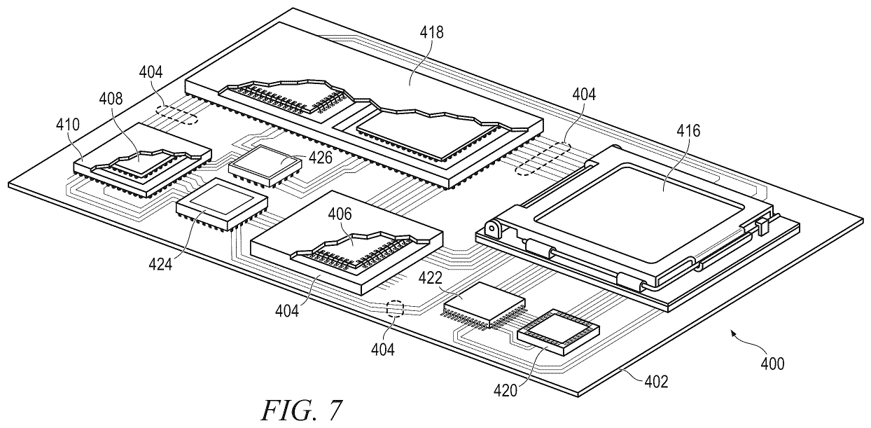

FIG. 7 illustrates electrical device 400 having a chip carrier substrate or PCB 402 with a plurality of semiconductor packages disposed on a surface of PCB 402, including vertical interconnect structures 174, 224, 230, and 240. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 7, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first conductive pillar;
a first encapsulant deposited around the first conductive pillar;
a second conductive pillar formed over the first conductive pillar; and
a second encapsulant deposited around the second conductive pillar.

2. The semiconductor device of claim 1, wherein the first conductive pillar includes an angled sidewall or a vertical sidewall.

3. The semiconductor device of claim 1, wherein the second conductive pillar includes an angled sidewall or a vertical sidewall.

4. The semiconductor device of claim 1, wherein a surface of the second conductive pillar exposed from the second encapsulant is planarized.

5. The semiconductor device of claim 1, wherein a width of the first conductive pillar is different from a width of the second conductive pillar.

6. The semiconductor device of claim 1, wherein a pitch of a sidewall of the first conductive pillar is different from a pitch of a sidewall of the second conductive pillar.

7. A semiconductor device, comprising a plurality of stacked encapsulated conductive pillar layers, each stacked encapsulated conductive pillar layer including,
(a) a conductive pillar, and
(b) an encapsulant deposited around the conductive pillar.

8. The semiconductor device of claim 7, wherein the conductive pillar includes an angled sidewall or a vertical sidewall.

9. The semiconductor device of claim 7, wherein the conductive pillar in a first stacked encapsulated conductive pillar layer contacts the conductive pillar in a second stacked encapsulated conductive pillar layer.

10. The semiconductor device of claim 9, wherein a width of the conductive pillar in the first stacked encapsulated conductive pillar layer is different from a width of the conductive pillar in the second stacked encapsulated conductive pillar layer.

11. The semiconductor device of claim 9, wherein a pitch of a sidewall of the conductive pillar in the first stacked encapsulated conductive pillar layer is different from a pitch of a sidewall of the conductive pillar in the second stacked encapsulated conductive pillar layer.

12. The semiconductor device of claim 7, wherein a surface of the conductive pillar exposed from the encapsulant is planarized.

13. The semiconductor device of claim 7, further including an electrical component disposed over the conductive pillar.

14. A method of making a semiconductor device, comprising:
forming a first conductive pillar;
depositing a first encapsulant around the first conductive pillar;
forming a second conductive pillar over the first conductive pillar; and
depositing a second encapsulant around the second conductive pillar.

15. The method of claim 14, wherein the first conductive pillar includes an angled sidewall or a vertical sidewall.

16. The method of claim 14, wherein the second conductive pillar includes an angled sidewall or a vertical sidewall.

17. The method of claim 14, further including planarizing a surface of the second conductive pillar.

18. The method of claim 14, wherein a width of the first conductive pillar is different from a width of the second conductive pillar.

19. The method of claim 14, wherein a pitch of a sidewall of the first conductive pillar is different from a pitch of a sidewall of the second conductive pillar.

20. A method of making a semiconductor device, comprising forming a plurality of stacked encapsulated conductive pillar layers, each stacked encapsulated conductive pillar layer being formed by,
(a) forming a conductive pillar, and
(b) depositing an encapsulant around the conductive pillar.

21. The method of claim 20, wherein the conductive pillar includes an angled sidewall or a vertical sidewall.

22. The method of claim 20, wherein the conductive pillar in a first stacked encapsulated conductive pillar layer contacts the conductive pillar in a second stacked encapsulated conductive pillar layer.

23. The method of claim 22, wherein a width of the conductive pillar in the first stacked encapsulated conductive pillar layer is different from a width of the conductive pillar in the second stacked encapsulated conductive pillar layer.

24. The method of claim 22, wherein a pitch of a sidewall of the conductive pillar in the first stacked encapsulated conductive pillar layer is different from a pitch of a sidewall of the conductive pillar in the second stacked encapsulated conductive pillar layer.

25. The method of claim 20, further including planarizing a surface of the conductive pillar.
